(19) United States
(12) Patent Application Publication
(10) Pub. No.: US 2005/0135232 A1
(43) Pub. Date: Jun. 23, 2005

(54) Transmission apparatus having a function of changing path setting

(76) Inventor: Susumu Taneoka, Yokohama (JP)

Correspondence Address: KATTEN MUCHIN ZAVIS ROSENMAN, 575 MADISON AVENUE, NEW YORK, NY, 10022-2585, US

(21) Appl. No.: 10/851,705

(22) Filed: May 20, 2004

(30) Foreign Application Priority Data
Dec. 19, 2003 (JP) 2003-423603

(51) Int. Cl. H04L 12/26; G01R 31/08

(52) U.S. Cl. 370/216; 370/242

(57) ABSTRACT

To provide a transmission apparatus and a transmission method in which change of connection information (settings) on an operation side of all transmission apparatuses is carried out in a state in which all the transmission apparatuses are synchronized with one another without interrupting a service for a path line of End-to-End. The transmission apparatus for carrying out transmission of information to/from other transmission apparatuses through a transmission line stores a setting of a path for transmission of information to/from other transmission apparatuses in an operation side setting unit, stores a setting after change of the path in a non-operation side setting unit, stores time for changing the path to output an instruction to change the path at a timing synchronous with the other transmission apparatuses based on the time for the change, and switches a path based on the setting on an operation side such that the path is set on a non-operation side in response to the instruction for the change.

### BACKGROUND OF THE INVENTION

The present invention relates to a technology for enabling an accommodated line to be changed while continuing a service in a network such as a SONET/SDH.

Conventionally, when upgrade such as expansion of a line capacity of a network is carried out, in case of a network having a linear configuration, after line switching was carried out between two stations after completion of expansion of a capacity of a non-operation line, the capacity of a line newly becoming a non-operation line is expanded. Alternatively, in case of a network having a ring (UPSR) configuration, in order to prevent a path signal from a line (section) as an object of upgrade from being communicated, after the direction of a path is fixed (forcedly switched) by two stations, the expansion of a capacity is carried out.

In such a conventional SONET system, when change in configuration is intended to be carried out, in general, the configuration change is carried out in a state in which lines currently in connection state and in service are all disconnected.

On the other hand, there is proposed an upgrading method in which in order to exchange a high speed side interface of a system for a higher speed interface in an in-service state, a signal line to which interchangeability with a low speed side interface device is provided is disposed such that a low speed side interface device of a transmission apparatus is installed in a position where a high speed side interface device of the transmission apparatus using an ADM apparatus in which a cross-connect function is provided for both an existing transmission apparatus and a high speed transmission apparatus to be newly added (refer to Patent document 1).

In addition, with respect to a line connection change system of a SONET transmission apparatus, there is proposed a line connection change system in which: an HMI control unit analyzes a request made in the form of a command inputted through a terminal to judge whether or not conditions under which the request can be executed are all met; if the execution is possible, the HMI control unit makes an execution request for a main control unit; the main control unit, in response to the execution request, searches a line connection information management unit to acquire line connection information currently in service and carries out connection for a line connection section so as for the connection to correspond to input destination information and output destination information of a line currently in service in accordance with a line connection instruction; and after completion of a connection processing for a line, the connection of the line connected before the execution of the processing is disconnected to thereby allow the line connection to be changed in an in-service state (while continuing a service) in speed unit of the line connection from a service line A/a line speed Nbps to a service line B/a line speed Mbps, for example, without a change of a physical medium (refer to Patent document 2).

[Patent document 1] JP 8-335922 A

[Patent document 2] JP 9-36882 A

### SUMMARY OF THE INVENTION

As described above, in the method in which interchangeability is provided between the high speed interface device to be newly added and the existing interface device, there arises a problem in that it is necessary to newly add the high speed interface device having a cross-connect function, and hence a system configuration becomes complicated.

In addition, in the system in which the connection processing for the line is executed when the conditions under which the request inputted through the terminal can be executed are all met, the exchange is carried out within the lines managed by the main control unit of the transmission apparatus, but a path line of End-to-End passing through a plurality of transmission apparatus are not switched in a state in which the plurality of transmission apparatuses are synchronized with one another.

On the other hand, in the existing transmission apparatus, it is generally carried out that when a failure occurs, an operation side is changed over to a non-operation side by utilizing the cross-connect function to avoid a failure without interrupting a service. The existing line is desirably changed over to a line after upgrade by utilizing the existing cross-connect function. However, even if for example, connection information after upgrade is set on a connection control unit on a non-operation side, the setting is simultaneously influenced on the operation side or altered into the same setting as that on the operation side in order to realize redundancy, and hence the setting for upgrade cannot be carried out temporarily. In addition, there is caused a problem in that a change is given to an actual connection state of a signal concurrently with the setting, so that change cannot be carried out synchronously with another transmission apparatus.

In the light of the above, the present invention provides a technology with which in order to carry out expansion of a line capacity for accommodation of a path and transfer of a line for accommodation of a path without interrupting a service for the path line of End-to-End, change of connection information of all transmission apparatuses (Add/Drop/Through) for accommodation of the path concerned is set independently between an operation side and a non-operation side, and the change on the operation side is carried out in a state in which all the transmission apparatuses are synchronized with one another.

In order to attain the object, the present invention adopts the following means.

A transmission apparatus according to the present invention, includes: an operation side setting unit that stores a setting of a path for transmission of information to/from other transmission apparatuses; a non-operation side setting unit that stores a setting after change of the path; a change reservation unit that stores time for changing the path to output an instruction to change the path at a timing synchronous with the other transmission apparatuses based on the time for the changing; and a switching unit that switches a path based on a setting on the operation side such that the path is set on a non-operation side in response to the instruction for the change.

That is to say, the transmission apparatus includes means that sets connection information for changing connection on a non-connection side of a connection control unit that controls connection information of a path line, or means that provides two spaces for a setting of connection information of a connection control unit to set the two spaces independently of each other, wherein switching from the operation side over to the non-operation side is possible.

Accordingly, it becomes possible to change a path in order to carry out expansion of a transmission line or a detour to other paths without interrupting a service for a path of End-to-End.

The transmission apparatus may be configured so as to include a path management unit that, in reservation of change in which a setting for changing the path is received, stores the setting of the change in the non-operation side setting unit, and that, in non-reservation until reception of the next path change after change of a path based on the setting, reflects the setting of a path stored in the operation side setting unit on the non-operation side setting unit,
wherein when a failure occurs in a path which is set through an operation system transmission line, based on a setting made by the operation side setting unit, of transmission lines to which the operation system transmission line and a spare system transmission line are provided for redundancy, if the failure occurrence is in the non-reservation, the switching unit carries out automatic relief for switching a path of the operation system transmission line such that the path is set through the spare system transmission line based on a setting of the non-operation system setting unit, and when the failure occurs, if the failure occurrence is in the reservation of change, the switching unit prohibits the automatic relief.

Accordingly, normally (in the non-reservation), redundancy is provided to the setting of an operation side setting unit and a non-operation side setting unit to make possible the automatic relief by the switching unit in occurrence of a failure, and in the reservation of change, the automatic relief is prohibited to allow a setting of path change to be independently written (recorded) to the non-operation side setting unit. Consequently, an automatic relief function and a function of changing a path can be realized with the same switching unit to realize simplification of an apparatus configuration.

In addition, the change reservation unit may make the synchronization with other transmission apparatuses based on a network time protocol to output the instruction for the changing at the reservation time to thereby carry out change of a path at the same time that the other transmission apparatuses make change of a path.

Further, in a transmission method according to the present invention, a transmission apparatus for carrying out transmission of information to/from other transmission apparatuses through a transmission line executes the steps of: storing a setting of a path for transmission of information to/from other transmission apparatuses in an operation side setting unit; storing a setting after change of the path in a non-operation side setting unit; storing time for changing the path to output an instruction to change the path at a timing synchronous with the other transmission apparatuses based on the time for the change; and switching a path based on the setting on an operation side such that the path is set on a non-operation side in response to the instruction for the change.

The transmission method may include the step of, in reservation of change in which a setting for changing the path is received, storing the setting of the change in the non-operation side setting unit, and in change mode release until reception of the next path change after change of a path based on the setting, reflecting the setting of a path stored in the operation side setting unit on the non-operation side setting unit, wherein when a failure occurs in a path based on the setting in the operation side setting unit through an operation system transmission line of transmission lines to which the operation system transmission line and a spare system transmission line are provided for redundancy, if the failure occurrence is in non-reservation, there is carried out automatic relief for switching a path based on the setting in the operation side setting unit such that the path is set through the spare system transmission line based on the setting in the non-operation system setting unit, and when the failure occurs, if the failure occurrence is in the change reservation, the automatic relief is prohibited.

In the transmission method, the synchronization may be made with other transmission apparatuses based on a network time protocol to output the instruction for the change at the reservation time to thereby carry out change of a path at the same time that the other transmission apparatuses make change of a path.

Note that in the transmission apparatus and transmission method, the change of the path may be transfer to an expanded transmission line, transfer to an empty line, or a detour to other paths.

According to the present invention, it is possible to provide a technology for carrying out the change of connection information (settings) in a state in which all the transmission apparatuses are synchronized with one another without interrupting the service for the path line of End-to-End.

### BRIEF DESCRIPTION OF THE DRAWINGS

FIG.1 is a diagram useful in explaining path change when a transmission line is expanded (version up) in a SONET/SDH constituted of transmission apparatuses according to the present invention.

FIG.2 is a diagram useful in explaining path change when a transmission line is expanded (version up) in a SONET/SDH constituted of transmission apparatuses according to the present invention.

FIG.3 is a diagram of a schematic configuration of a transmission apparatus according to the present invention.

FIG.4 is a diagram of a schematic configuration of a system according to the present invention in which the transmission apparatuses are connected to one another through a transmission line to constitute a ring-like network.

FIG.5 is a diagram useful in explaining a command processing for a path setting request or the like and a processing in occurrence of a failure.

FIG.6 is a diagram useful in explaining a time setting processing for synchronization with other transmission apparatuses.

FIG.7 is a diagram useful in explaining a time setting processing for synchronization with other transmission apparatuses.

FIG.8 is a diagram showing a network configuration after expansion of a line.

FIG.9 is a diagram useful in explaining a processing for starting setting change (a processing for setting a mode to a change mode).

FIG.10 is a diagram useful in explaining a processing for reserving a setting after change.

FIG.11 is a diagram useful in explaining a connection information table of a non-operation side setting unit.

FIG.12 is a diagram useful in explaining a processing for setting reservation time for change.

FIG.13 is a diagram useful in explaining a processing for switching a setting executed at reservation time.

### DETAILED DESCRIPTION OF THE PREFERRED EMBODIMENT

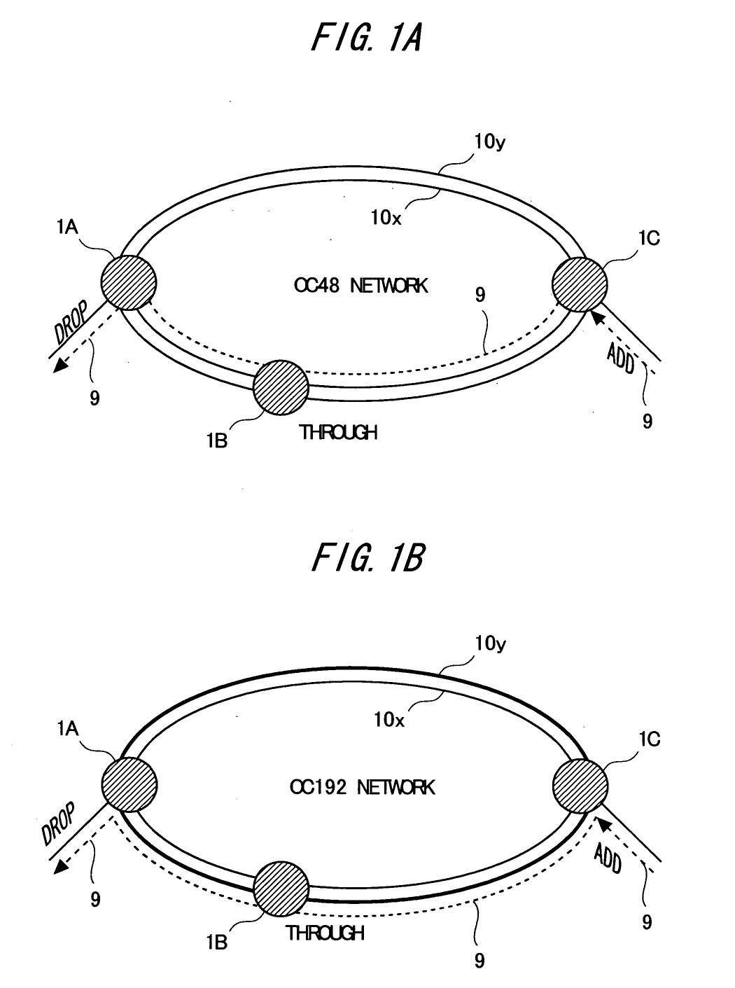

Transmission apparatuses as embodiment modes of the present invention, and a transmission system configured with the transmission apparatuses will hereinafter be described on the basis of the drawings of FIGS. 1 to 13.

### Embodiment Mode 1

§1. Description of Principles of the System

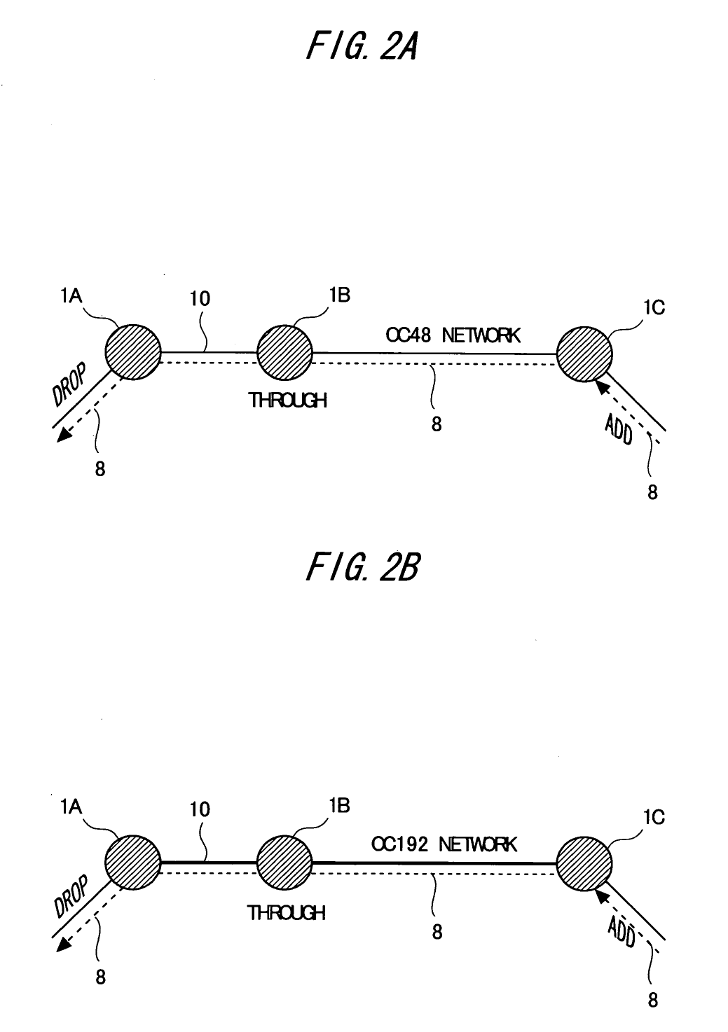

FIGS. 1 and 2 are views useful in explaining path change when a transmission line is expanded (version up) in an SONET/SDH configured with the transmission apparatuses according to the present invention.

FIG. 1(a) shows a network configuration before upgrade in which transmission apparatuses 1A, 1B, and 1C are connected to one another in a ring-like manner through an inner transmission line 10x and a spare system transmission line 10y of an OC48.

A path 9 in which information is added to the inner transmission line 10x in the transmission apparatus 1C, and is passed through the transmission apparatus 1B, and is dropped in the transmission apparatus 1A is set in the network. Note that while in the figure, only the clockwise path is shown, the same information, for redundancy, is transmitted through the counterclockwise path as well.

Then, as shown in FIG. 1(b), after the outer transmission line 10y is upgraded to an OC192, the path 9 is set in the outer transmission line 10y.

In addition, in FIG. 2(a), the transmission apparatuses 1A, 1B, and 1C are linearly connected to one another through a transmission line 10 of the OC48.

A path 8 in which information is added to the transmission line 10 in the transmission apparatus 1C, and is passed through the transmission apparatus 1B, and is dropped in the transmission apparatus 1A is set in the network.

Then, as shown in FIG. 2(b), after the transmission line 10 is upgraded to the OC192, with respect to the path 8, a setting for the OC48 is changed over to a setting for the OC192. In such a manner, in the present invention, change such as expansion of the transmission line is carried out in an in-service state.

§2. Configuration of Transmission Apparatus

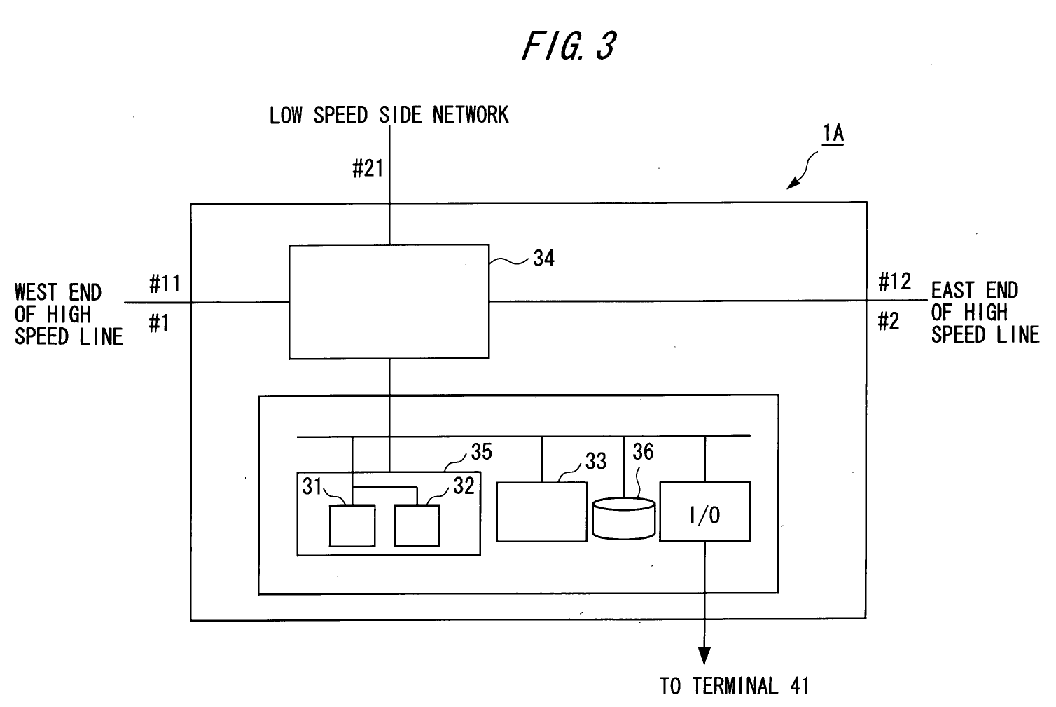

FIG. 3 is a diagram of a schematic configuration of the transmission apparatus 1A according to the present invention which enables change of a path possible in the in-service state.

The transmission apparatus 1A includes an operation side setting unit 31, a non-operation side setting unit 32, a change reservation unit 33, a switching unit 34, a path management unit 35, and a storage unit 36.

The operation side setting unit 31 stores a setting of a path for transmission of information to/from other transmission apparatuses. The non-operation side setting unit 32 stores a setting of the path after change for automatic relief, upgrade, or the like.

The path management unit 35, when setting information of a path is inputted through an external terminal, writes and stores the setting information in a connection information table of the operation side setting unit 31 or the non-operation side setting unit 32. For example, when a setting of a path is inputted in a normal operation, the setting is stored in the operation side setting unit 31, and at the same time, the setting, for redundancy, is simultaneously reflected on the non-operation side setting unit 32.

Then, the path management unit 35, when a setting of change of a path in upgrading the transmission line 10 is received (in a change mode), stores the setting of change in the non-operation side setting unit. That is to say, in the change mode, a setting of the path after change is recorded in the non-operation side setting unit 32 separately from the setting in the operation side setting unit 31.

In addition, the path management unit 35 carries out monitoring for a failure of a high speed line 10 or the like, and when detecting occurrence of a failure, informs the switching unit 34 of occurrence of the failure to cause the switching unit 34 to carry out automatic relief.

The change reservation unit 33 has a memory for storing information related to path change, and stores the time of change in a reservation table built in the memory. Then, the change reservation unit 33 outputs an instruction to change the path at a timing synchronous with other transmission apparatuses on the basis of the change time. The change reservation unit 33 also stores, in addition to the change time, information concerned with whether an automatic relief prohibition mode is ON or OFF, and setting information of a time setting mode in the memory. In addition, the change reservation unit 33 has a timer (clock LSI) for outputting a change instruction at the reservation time, and carries out the time setting for the timer by referring to the time of an NTP server (which will be described later) in accordance with an NTP (Network Time Protocol). In such a manner, the transmission apparatus 1A (1B, 1C, or 1D) constituting-the network carries out the time setting to the time set in the NTP server to be synchronous in time with other transmission apparatuses to carry out change of a path simultaneously with other transmission apparatuses.

The switching unit 34, when a failure occurs in a path which is set through an operation system transmission line, on the basis of a setting in the operation side setting unit, of transmission lines to which the operation system transmission line and a spare system transmission line are provided for redundancy, if the failure occurrence is in release of the change mode, carries out automatic relief for changing a path of the operation system transmission path such that the path is set through the spare system transmission line on the basis of a setting in the non-operation system setting unit. In addition, when the failure occurs, if the failure occurrence is in the change mode, then the switching unit 34 prohibits the automatic relief. In addition, the switching unit 34 switches a path based on the setting on the operation side such that the path is set on the non-operation side.

The storage unit 36 stores a setting in the operation side setting unit 31, a setting in the non-operation side setting unit 32, information in the reservation table, operation data, and the like in a nonvolatile memory to carry out backup.

§3. Schematic Configuration of the System

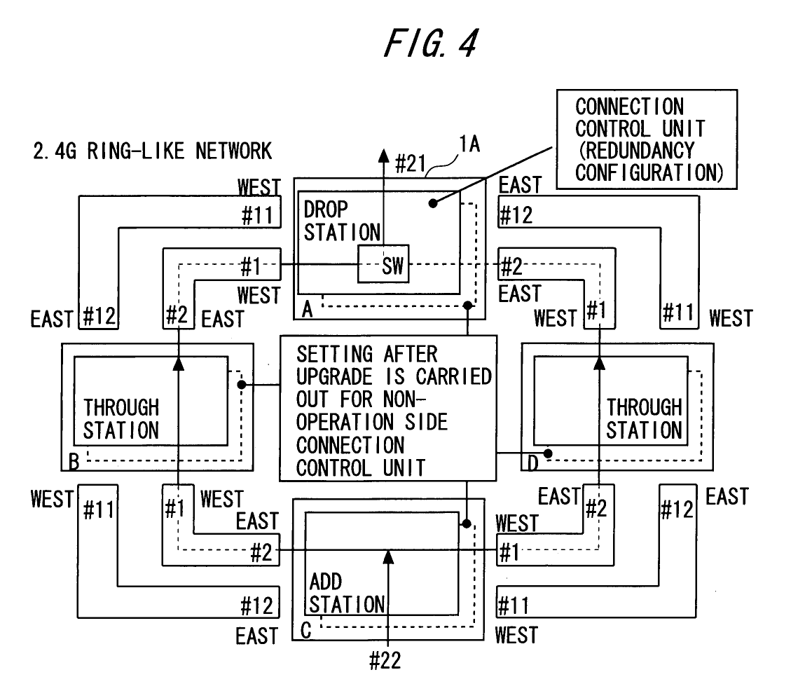

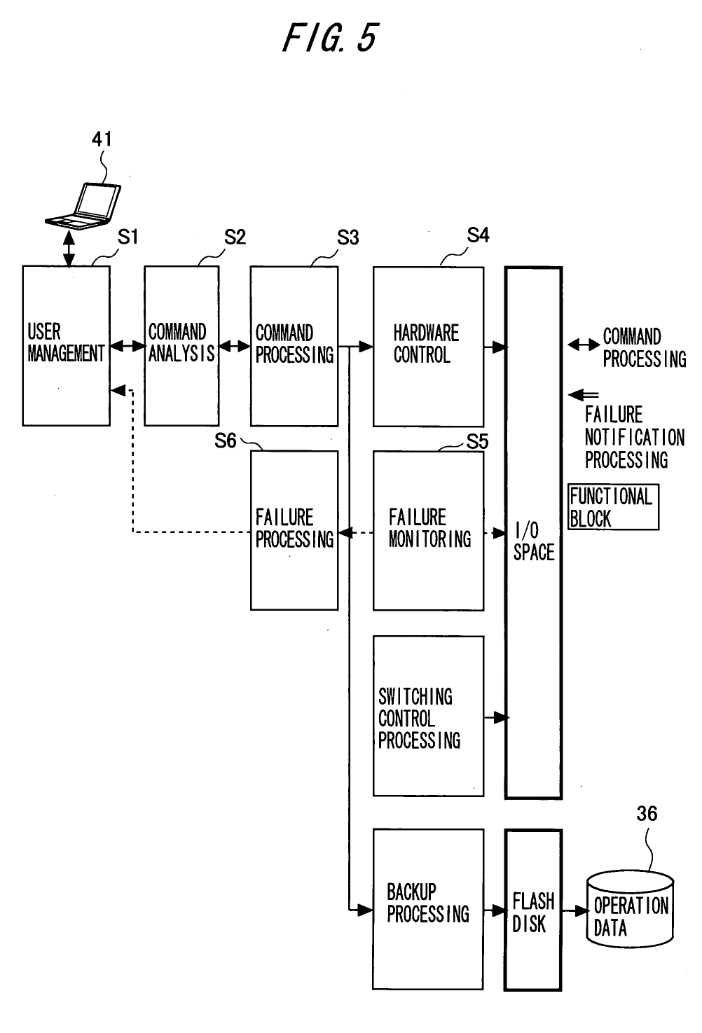

FIG. 4 is a diagram of a schematic configuration of the system in which the transmission apparatuses 1A to 1D are connected to one another through the transmission line 10 to constitute a ring-like network. The transmission apparatus 1A, and the transmission apparatuses 1B, 1C, and 1D are identical in configuration to one another. A terminal 41 (FIG. 5) is a terminal for maintenance which is connected to the transmission apparatus 1A and receives as its input a setting of a path, or the like. While omitted in the figure, terminals for maintenance are connected to other transmission apparatuses 1B to 1D, respectively. The terminals for maintenance may be provided separately so as to correspond to the transmission apparatuses, or may be connected to a plurality of transmission apparatuses 1A to 1D through a network.

The transmission line 10 includes the inner high speed line 10x and the outer high speed line 10y. In addition, each of the inner high speed line 10x and the outer high speed line 10y shown in FIG. 4 has a line speed of 2.4 GB.

§4. Description of Function of the System

(4-1) Command Processing and Failure Processing

Next, a command processing for a path setting request or the like and a processing in occurrence of a failure will hereinafter be described using FIG. 5.

First of all, at the time when a user gains access to the transmission apparatus 1A through the terminal 41, the transmission apparatus 1A carries out user management such as authentication (Step 1; Steps will hereinafter be abbreviated in the form of S1 and the like). When a user who has been authenticated by the transmission apparatus 1A and completed log-in inputs a command to the transmission apparatus 1A, the transmission apparatus 1A analyzes the command (S2) to execute a processing on the basis of the analysis results (S3), and when the processing is concerned with a hardware, carries out hardware control (S4). If the processing for the command, for example, is a request to set a path, then the transmission apparatus 1A writes (stores) a setting inputted by the path management unit 35 to the operation side setting unit 31, and also reflects the setting on the non-operation side setting unit 32 as well. In addition, these settings are stored as a backup in the storage unit 36.

Thus, the transmission apparatus 1A, in the normal operation, carries out the transmission in accordance with the setting in the operation side setting unit 31. If the setting, for example, is a setting as a drop station, then information transmitted through the high speed line 10 is dropped to the network on a low speed side. In addition, a setting as a through station or a drop station as well is similarly carried out.

Then, a failure is monitored by the path management unit 35 of the transmission apparatus 1A (S5). When a failure in the high speed line 10 or the like is detected, a failure processing is executed (S6). That is to say, the path management unit 35 informs the switching unit 34 of occurrence of a failure, and the switching unit 34 switches the current setting over to a setting in the non-operation side setting unit 32 to carry out the automatic relief.

Each of the transmission apparatuses 1B, 1C, and 1D, similarly to the transmission apparatus 1A, executes the command processing and the failure processing.

(4-2) Time Setting Processing

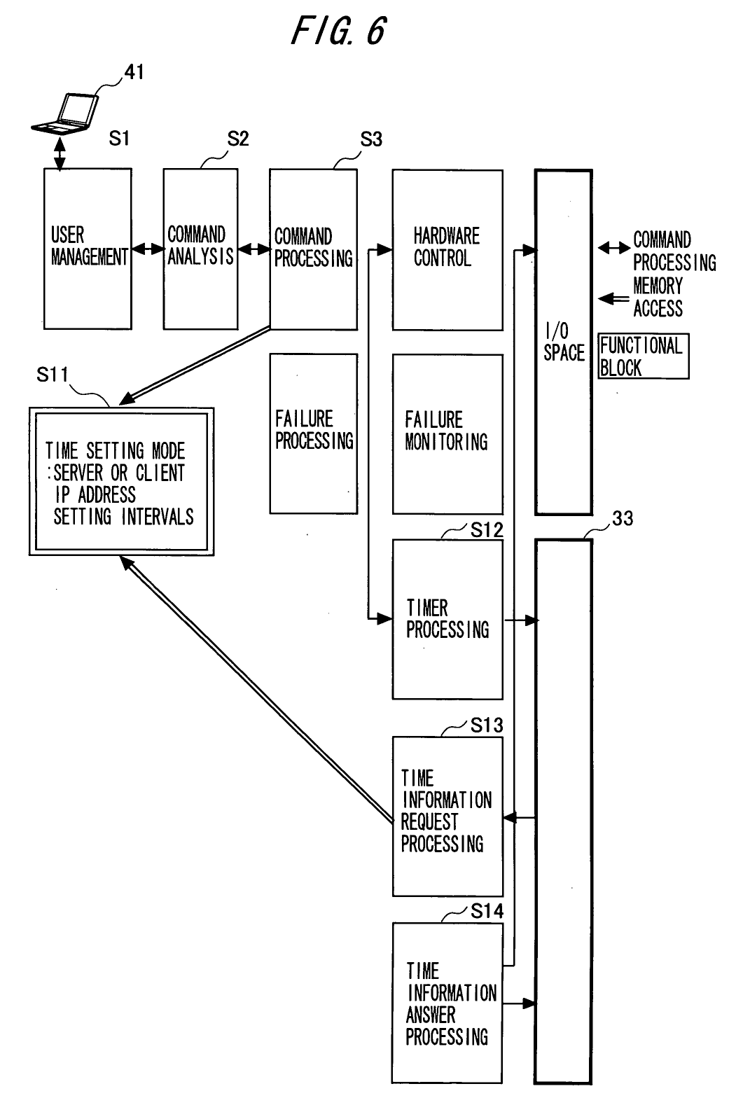

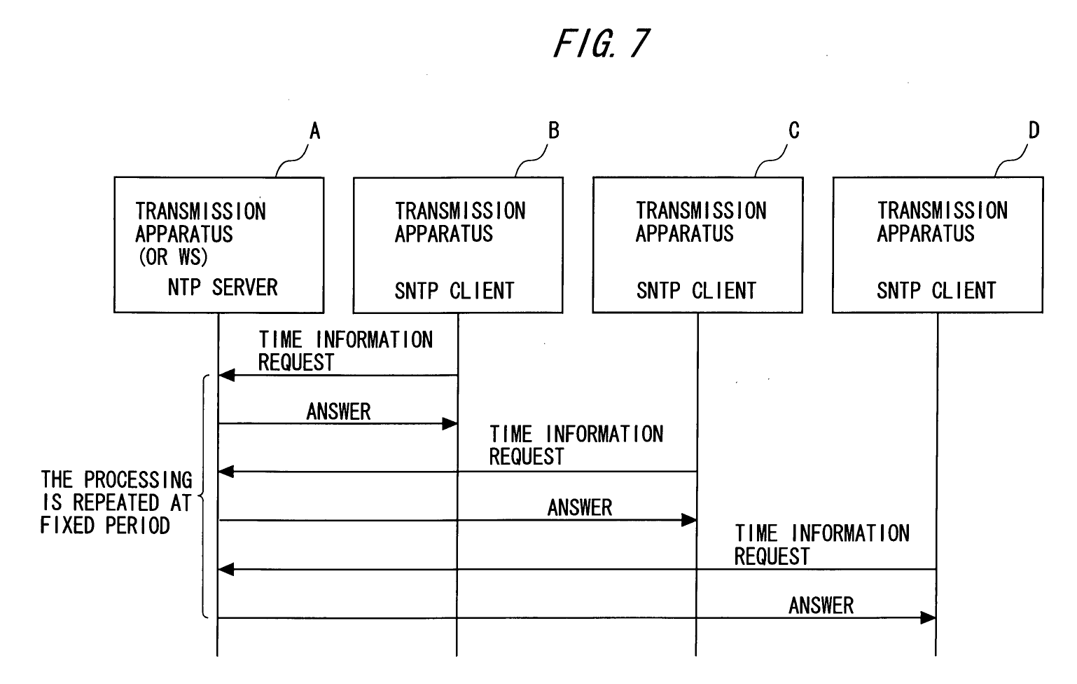

FIGS. 6 and 7 are diagrams useful in explaining a time setting processing for synchronization with other transmission apparatuses.

At the time when a command to set a time setting mode is inputted through the terminal 41 in accordance with a manipulation made by a user, the transmission apparatus 1A, similarly to the foregoing, executes user authentication, command analysis, and a command processing (S1 to S3), and stores setting information of the time setting mode in the memory of the change reservation unit 33 in accordance with the command (S11). The setting information of the time setting mode, for example, is information exhibiting whether a mode concerned is a server mode or a client mode. When the information exhibiting the client mode is stored, i.e., when the client mode is set, an IP address and setting intervals of an NTP server are further stored as the setting information of the time setting mode.

In addition, when the client mode is set, a timer processing (S12) is activated in the change reservation unit 33, and the NTP-server with the IP address is notified of a time request at the setting intervals by referring to the memory (S13). Then, at the time when acquiring the time information from the NTP server, the transmission apparatus 1A carries out the time setting of the timer on the basis of the time information.

Each of other transmission apparatuses 1B, 1C, and 1D, similarly to the transmission apparatus 1A, also executes the time setting processing.

In such a manner, a plurality of transmission apparatuses constituting the system carry out time settings on the basis of the time information from the NTP server, respectively, to thereby be synchronous in time with other transmission apparatuses.

In addition, in a case where the server mode is set in any one of a plurality of transmission apparatuses constituting the system, e.g., the transmission apparatus 1A through the command processing (S11), the transmission apparatus 1A concerned functions as the NTP server for supplying the time information to other transmission apparatuses 1B, 1C, and 1D. That is to say, as shown in FIG. 7, the transmission apparatuses 1B, 1C, and 1D send time information acquirement requests at predetermined periods to the transmission apparatus 1A, respectively, and then the transmission apparatus 1A, in response to these time information acquirement requests, acquires time information from a timer (clock LSI) to send the time information as an answer to each of the transmission apparatuses 1B, 1C, and 1D (S14).

(4-3) Processing for starting Setting Change

(Automatic Relief Prohibition Processing)

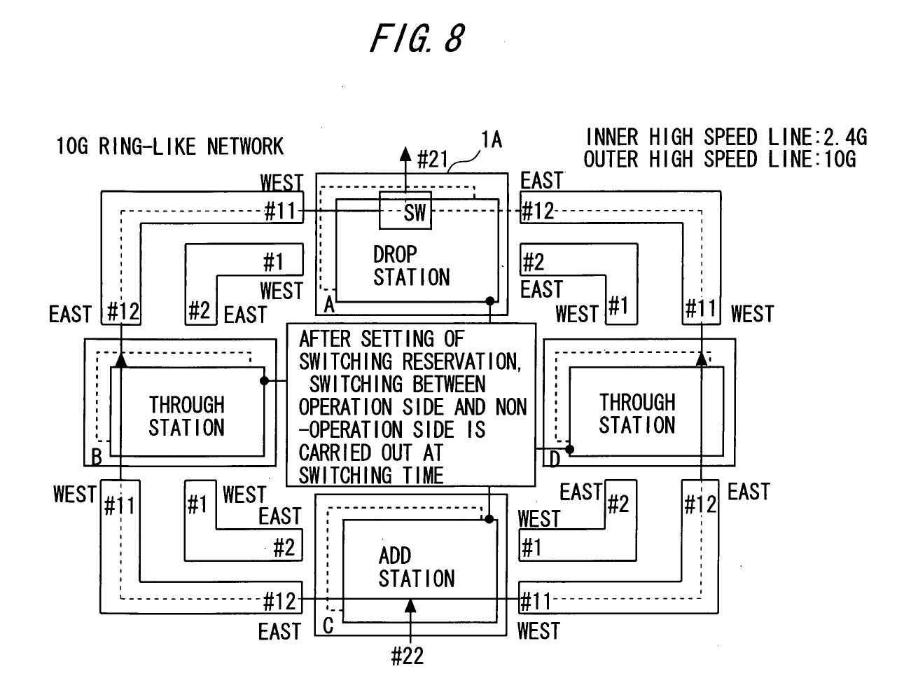

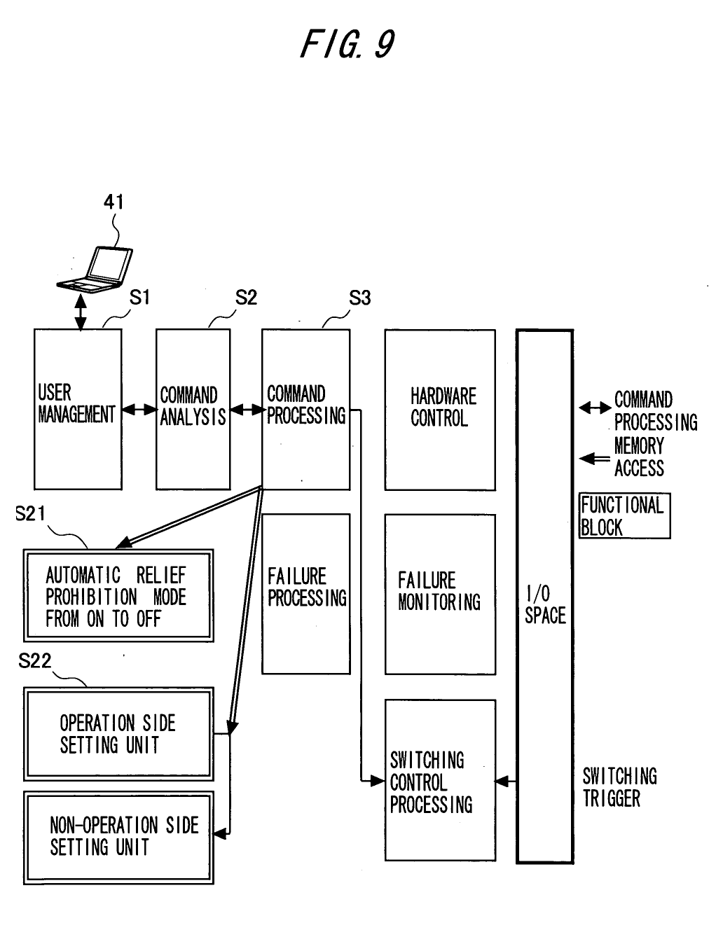

FIG. 8 is a diagram showing a network configuration after expansion of a line, and FIG. 9 is a diagram useful in explaining a processing for starting setting change (a processing for setting a change mode).

In expanding a line, first of all, as shown in FIG. 8, a line to be expanded is laid down. In the example, the outer high speed line 10y is expanded from 2.4 G to 10 G.

Then, at the time when a command to set a change mode is inputted from the terminal 41 to the transmission apparatus 1A in accordance with manipulation made by a user, the transmission apparatus 1A, similarly to the foregoing, executes user authentication, command analysis, and a command processing (S1 to S3), and records a flag exhibiting an automatic relief prohibition mode (i.e., a flag exhibiting a change mode) in the memory of the change reservation unit 33 in accordance with the command to set a change mode (S21).

In addition, the transmission apparatus 1A copies the setting on the operation side setting unit 31 to the non-operation side setting unit 32 (S22).

Likewise, a command to set a change mode is inputted to each of the transmission apparatuses 1B, 1C, and 1D to set an automatic relief prohibition mode (i.e., a change mode).

(4-4) Change Setting Processing

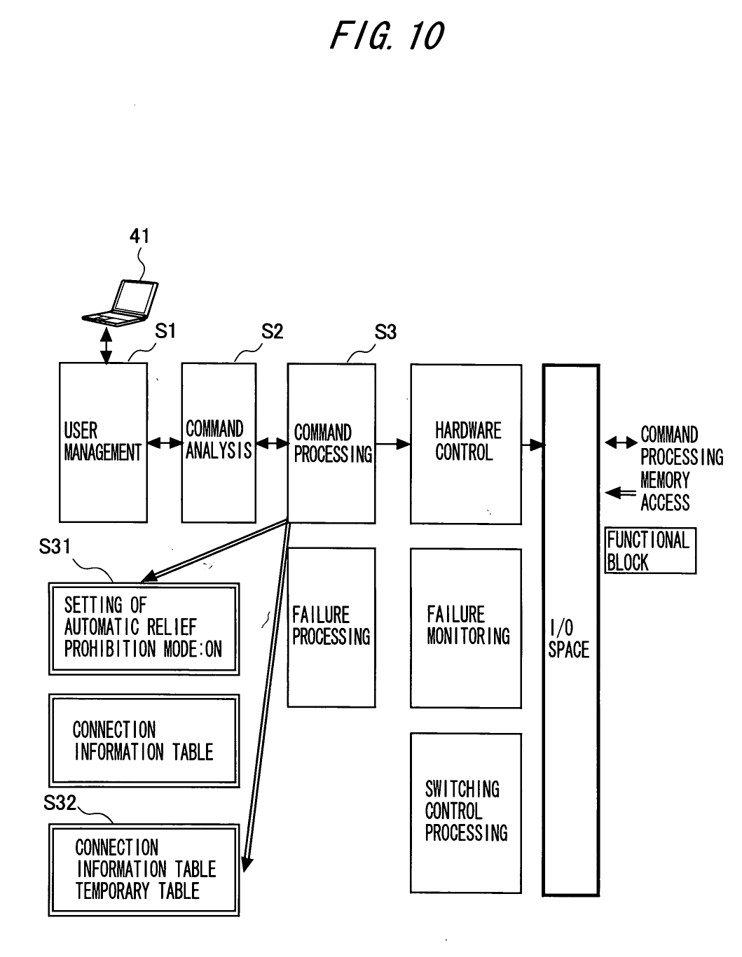

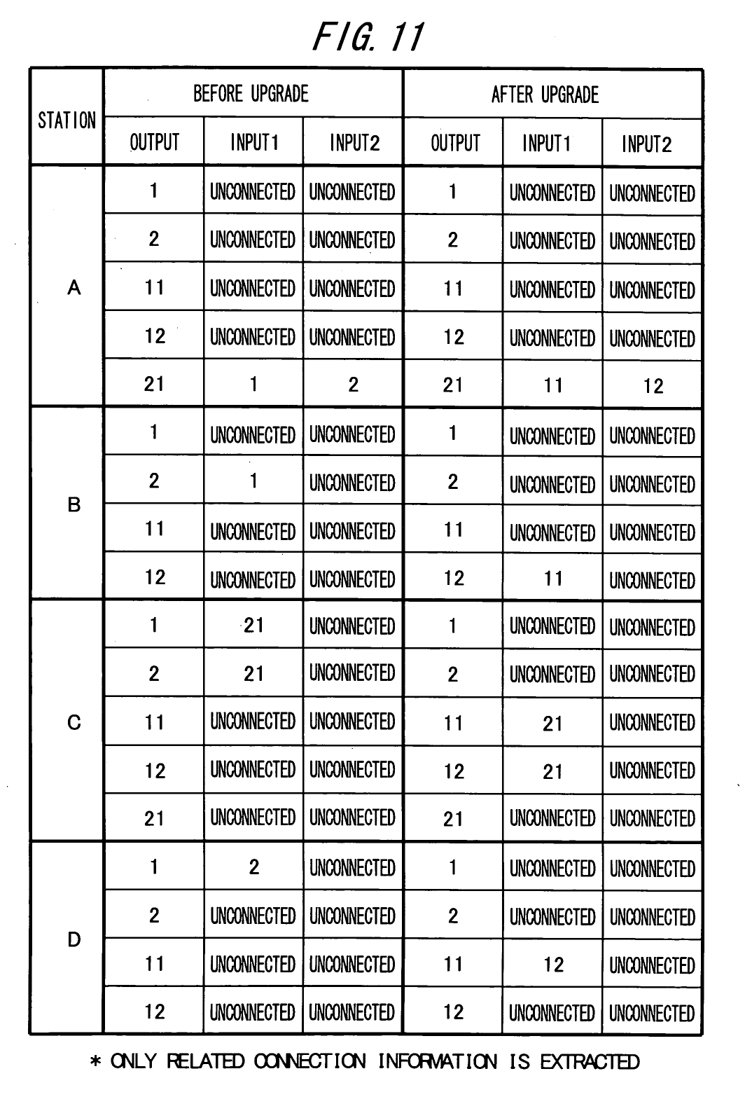

FIG. 10 is a diagram useful in explaining a processing for reserving a setting of a path after change, and FIG. 11 is a diagram useful in explaining a connection information table of the non-operation side setting unit. In FIG. 11, only information of the path shown in FIGS. 4 and 8 is extracted, and the setting before the change and the setting after the change are compared with each other.

The non-operation side setting unit 32, in the normal operation, for redundancy, stores the same setting as that in the operation side setting unit 31, i.e., the setting before the change shown in FIG. 10.

Then, at the time when a command to determine a setting after the change is inputted from the terminal 41 to the transmission apparatus 1A, the path management unit 35 of the transmission apparatus 1A verifies ON/OFF of the automatic relief prohibition mode flag by referring to the memory of the change reservation unit 33 (S31).

If the automatic relief prohibition mode flag is ON, then the path management unit 35 of the transmission apparatus 1A prohibits the path setting for redundancy to store the setting after the change in the non-operation side setting unit 32 (S32). Note that if the automatic relief prohibition mode flag is OFF, then reception of the setting after the change is not carried out.

Likewise, a command to determine the setting after the change is inputted to each of the transmission apparatuses 1B, 1C, and 1D to store the setting after the change in the non-operation side setting unit 32.

(4-5) Reservation Time Setting Processing

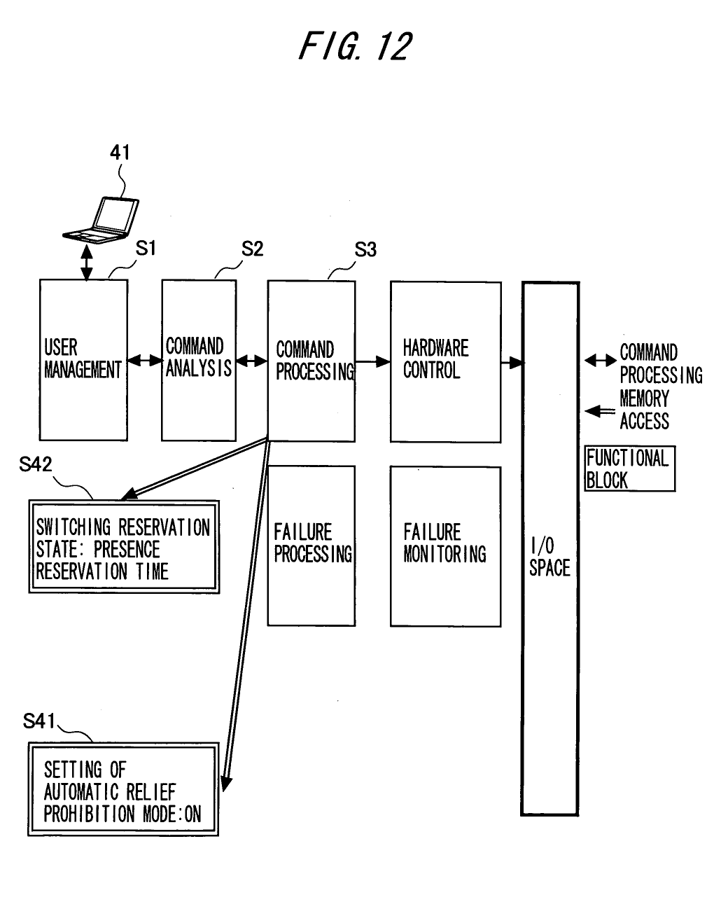

FIG. 12 is a diagram useful in explaining a processing for setting the reservation time of the change.

At the time when a command exhibiting the reservation time of the change is inputted from the terminal 41 to the transmission apparatus 1A, the change reservation unit 33 verifies ON/OFF of the automatic relief prohibition mode flag (S41).

If the automatic relief prohibition mode flag is ON, then the change reservation unit 33 of the transmission apparatus IA stores the reservation time of the change in a reservation table (S42). Note that if the automatic relief prohibition mode flag is OFF, then reception of the reservation time of the change is not carried out.

Likewise, a command exhibiting the reservation time of the change is inputted to each of the transmission apparatuses 1B, 1C, and 1D to store the reservation time of the change in the non-operation side setting unit 32.

(4-6) Processing for Switching a Setting

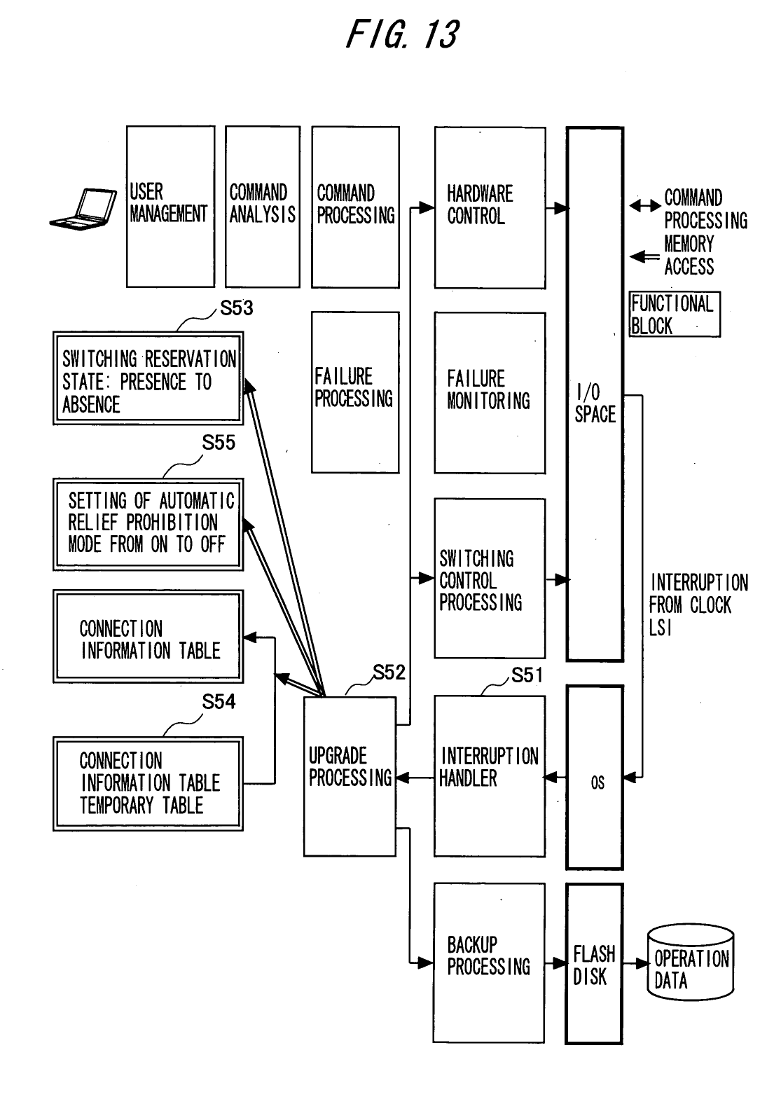

FIG. 13 is a diagram useful in explaining a processing for switching a setting which is executed at the reservation time.

As described above, after execution of the change setting processing, the setting before the change shown in FIG. 11 is stored in the connection information table of the operation side setting unit 31 and the setting after the change shown in FIG. 11 is stored in the connection information table of the non-operation side setting unit 32.

Consequently, in the connection information table of the operation side setting unit 31 of the transmission apparatus 1A as the drop station, the west end #1 of the inner high speed line 10x is set to an input 1, the east end #2 of the outer high speed line 10y is set to an input 2, and the low speed side line #21 is set to an output. That is to say, in the normal operation, a frame inputted through the west end #1 is dropped to the low speed side line #21, while in case of occurrence of a failure, a frame inputted through the west end #2 is dropped to the low speed side line #21.

Likewise, the transmission apparatus 1B as the through station makes a frame inputted through the west end #1 of the inner high speed line 10x pass through the east end #2 in accordance with the contents of the connection information table of the operation side setting unit 31.

The transmission apparatus 1C as the add station outputs a frame inputted through the low speed side line #22 to both the east end #2 and the west end #1 of the inner high speed line 10x in accordance with the contents of the connection information table of the operation side setting unit 31.

The transmission apparatus 1D as the through station makes a frame inputted through the east end #2 of the inner high speed line 10x pass through the west terminal #1 in accordance with the contents of the connection information table of the operation side setting unit 31.

Then, at the reservation time, the change reservation unit 33 of each of the transmission apparatuses 1A, 1B, 1C, and 1D detects on the basis of the current time of the timer and the reservation time within the memory that it is the reservation time to activate an interruption processing to output a change instruction to the switching unit 34 (S51).

The switching unit 34, in response to the change instruction, executes a processing for switching a setting (an upgrade processing in the example) (S52). That is to say, the switching unit 34 switches the setting in the operation side setting unit 31 over to the setting in the non-operation side setting unit 32 to carry out the transmission.

In the connection information table of the non-operation side setting unit 32 of the transmission apparatus 1A as the drop station, the west end #11 of the outer high speed line 10y is set to an input 1, the east end #12 of the outer high speed line 10y is set to an input 2, and the low speed side line #21 is set to an output. Consequently, the transmission apparatus 1A, in the normal operation, drops a frame inputted through the west end #11 to the low speed side line #21, and in case of occurrence of a failure, drops a frame inputted through the east end #12 to the low speed side line #21.

Likewise, the transmission apparatus 1B as the through station makes a frame inputted through the west end #1 of the inner high speed line 10x pass through the east end #2 in accordance with the contents of the connection information table of the non-operation side setting unit 32.

The transmission apparatus 1C as the add station outputs a frame inputted through the low speed side line #22 to both the east end #12 and the west end #11 of the outer high speed line 10y in accordance with the contents of the connection information table of the non-operation side setting unit 32.

The transmission apparatus 1D as the through station makes a frame inputted through the east end #2 of the outer high speed line 10y pass through the west terminal #1 in accordance with the contents of the connection information table of the non-operation side setting unit 32.

Then, after a lapse of a predetermined period of time from a time point of the setting change, the change reservation unit 33 outputs a change mode release instruction, or a user inputs a command to instruct release of the change mode from the terminal 41 to each of transmission apparatuses 1A, 1B, 1C, and 1D. When receiving the change mode release instruction, the path management unit 35 of each of the transmission apparatuses 1A, 1B, 1C, and 1D clears the reservation time stored in the reservation table of the change reservation unit 33 (S53), copies the setting in the non-operation side setting unit 32 to the operation side setting unit 31 (S54), and sets the automatic relief prohibition mode flag of the reservation table to OFF (S55) to release the change mode.

In such a manner, in the embodiment, the path through the inner high speed line 10x is changed so as to be set through the expanded outer high speed line 10y. At the time, the change is carried out in a state in which all the transmission apparatuses constituting the path are synchronized with one another, whereby the setting (connection information) of the path can be carried out without interrupting the service for the path line of End-to-End.

### Other Embodiment Modes

It is to be understood that the present invention is not intended to be limited to the illustrated example, and hence various changes may be made without departing from the subject matter of the invention.

1. A transmission apparatus, including:
an operation side setting unit that stores a setting of a path for transmission of information to/from other transmission apparatuses;
a non-operation side setting unit that stores a setting after change of the path;
a change reservation unit that stores time for changing the path to output an instruction to change the path at a timing synchronous with the other transmission apparatuses based on the time for the changing; and
a switching unit that switches a path based on a setting on the operation side such that the path is set on a non-operation side in response to the instruction for the changing.

2. The transmission apparatus according to claim 1, including a path management unit that, in reservation of change in which a setting for changing the path is received, stores the setting of the change in the non-operation side setting unit, and that, in non-reservation until reception of the next path change after change of a path based on the setting, reflects the setting of a path stored in the operation side setting unit on the non-operation side setting unit,
in which when a failure occurs in a path which is set through an operation system transmission line, based on a setting made by the operation side setting unit, of transmission lines to which the operation system transmission line and a spare system transmission line are provided for redundancy, if the failure occurrence is in the non-reservation, the switching unit carries out automatic relief for switching a path of the operation system transmission line such that the path is set through the spare system transmission line based on a setting of the non-operation system setting unit, and when the failure occurs, if the failure occurrence is in the reservation of change, the switching unit prohibits the automatic relief.

3. The transmission apparatus according to claim 1, in which the change reservation unit makes the synchronization with other transmission apparatuses based on a network time protocol to output the instruction for the changing at the reservation time to thereby carry out change of a path at the same time that the other transmission apparatuses make change of a path.

4. The transmission apparatus according to claim 1, in which the change of the path is transfer to an expanded transmission line, transfer to an empty line, or a detour to other paths.

5. A transmission method, in which a transmission apparatus for carrying out transmission of information to/from other transmission apparatuses through a transmission line executes the steps of:
storing a setting of a path for transmission of information to/from other transmission apparatuses in an operation side setting unit;
storing a setting after change of the path in a non-operation side setting unit;
storing time for changing the path to output an instruction to change the path at a timing synchronous with the other transmission apparatuses based on the time for the change; and
switching a path based on the setting on an operation side such that the path is set on a non-operation side in response to the instruction for the change.

6. The transmission method according to claim 5, including the step of, in reservation of change in which a setting for changing the path is received, storing the setting of the change in the non-operation side setting unit, and in change mode release until reception of the next path change after change of a path based on the setting, reflecting the setting of a path stored in the operation side setting unit on the non-operation side setting unit, in which when a failure occurs in a path based on the setting in the operation side setting unit through an operation system transmission line of transmission lines to which the operation system transmission line and a spare system transmission line are provided for redundancy, if the failure occurrence is in non-reservation, there is carried out automatic relief for switching a path based on the setting in the operation side setting unit such that the path is set through the spare system transmission line based on the setting in the non-operation system setting unit, and when the failure occurs, if the failure occurrence is in the change reservation, the automatic relief is prohibited.

7. The transmission method according to claim 5, in which the synchronization is made with other transmission apparatuses based on a network time protocol to output the instruction for the change at the reservation time to thereby carry out change of a path at the same time that the other transmission apparatuses make change of a path.

8. The transmission method according to claim 5, in which the change of the path is transfer to an expanded transmission line, transfer to an empty line, or a detour to other paths.
